(19) United States
(12) Patent Application Publication
(10) Pub. No.: US 2024/0012751 A1
(43) Pub. Date: Jan. 11, 2024

(54) ADAPTIVE WEAR LEVELING FOR A MEMORY SYSTEM

(71) Applicant: Micron Technology, Inc., Boise, ID (US)

(72) Inventors: John J. Kane, Westminster, CO (US); Byron D. Harris, Mead, CO (US); Vivek Shivhare, Milpitas, CA (US)

(21) Appl. No.: 17/811,796

(22) Filed: Jul. 11, 2022

(51) Int. Cl. G06F 12/02; G06F 3/06

(52) U.S. Cl. CPC G06F 12/0238; G06F 3/0616; G06F 3/0655; G06F 3/0679; G06F 2212/7211

(57) ABSTRACT

Methods, systems, and devices for adaptive wear leveling for a memory system are described. A memory system may implement an adaptive rate for performing various wear leveling operations, such as an adaptive rate for performing wear leveling evaluations, or an adaptive rate for performing wear leveling data transfers, among other examples. For example, a memory system may begin with or default to performing wear leveling operations in accordance with a relatively slower rate, and adjust (e.g., accelerate) wear leveling operations based on detecting a relatively greater demand to perform wear leveling operations. In some such examples, wear leveling operations may be capped at a rate (e.g., a maximum rate), which may limit a degradation of memory system performance while performing wear leveling operations. As wear distribution improves, the memory system may adjust (e.g., decelerate) wear leveling operations.

### FIELD OF TECHNOLOGY

The following relates to one or more systems for memory, including adaptive wear leveling for a memory system.

### BACKGROUND

Memory devices are widely used to store information in various electronic devices such as computers, user devices, wireless communication devices, cameras, digital displays, and the like. Information is stored by programming memory cells within a memory device to various states. For example, binary memory cells may be programmed to one of two supported states, often corresponding to a logic 1 or a logic 0. In some examples, a single memory cell may support more than two possible states, any one of which may be stored by the memory cell. To access information stored by a memory device, a component may read (e.g., sense, detect, retrieve, identify, determine, evaluate) the state of one or more memory cells within the memory device. To store information, a component may write (e.g., program, set, assign) one or more memory cells within the memory device to corresponding states.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), 3-dimensional cross-point memory (3D cross point), not-or (NOR) and not-and (NAND) memory devices, and others. Memory devices may be described in terms of volatile configurations or non-volatile configurations. Volatile memory cells (e.g., DRAM) may lose their programmed states over time unless they are periodically refreshed by an external power source. Non-volatile memory cells (e.g., NAND) may maintain their programmed states for extended periods of time even in the absence of an external power source.

### BRIEF DESCRIPTION OF THE DRAWINGS

FIG. 1 illustrates an example of a system that supports adaptive wear leveling for a memory system in accordance with examples as disclosed herein.

FIG. 2 illustrates an example of a process flow that supports adaptive wear leveling for a memory system in accordance with examples as disclosed herein.

FIG. 3 shows a block diagram of a memory system that supports adaptive wear leveling for a memory system in accordance with examples as disclosed herein.

FIGS. 4 through 6 show flowcharts illustrating methods that support adaptive wear leveling for a memory system in accordance with examples as disclosed herein.

### DETAILED DESCRIPTION

In some memory architectures, memory cells may degrade over an operable life of a memory system. For example, NAND memory cells, among other examples, may degrade over an accumulation of access operations, which may be associated with relatively large signals (e.g., relatively high voltages) applied to memory cells during program operations, during erase operations, during other operations, or various combinations thereof. To extend operable life, some memory systems may implement wear leveling techniques to mitigate adverse effects associated with certain memory cells degrading at different rates (e.g., more quickly) than others, which may include distributing access-based degradation more evenly across memory cells of the memory system. In some examples, the wear leveling techniques may involve a background process of moving data that is modified or otherwise accessed relatively infrequently to memory cells that have been accessed (e.g., written to, erased) relatively more frequently, which may reduce an accumulation of degradation by those memory cells that have been accessed relatively more frequently.

In some memory applications, some memory cells may be written with data that is relatively static (e.g., an operating system or other data that is retained for a relatively long duration with little or no modification) whereas other memory cells may be written with data that is relatively transient (e.g., data that may be unneeded or deleted within a relatively short duration, data that is modified relatively frequently). For applications that implement wear leveling (e.g., NAND memory), a relatively large quantity of memory cells written with static data may become candidates for wear leveling within a short duration (e.g., those memory cells that were written to with static data, such as an operating system or archival data, without being moved or erased over a long duration, while other memory cells may be accumulating access operation cycles). However, performing a relatively large quantity of wear leveling operations (e.g., wear leveling evaluations, wear leveling data transfers) within a relatively short duration may impair an ability of the memory system to perform other operations (e.g., operations for supporting access by a host system), which may at least temporarily reduce a quality of service supported by the memory system (e.g., associated with increased latency, associated with reduced throughput).

In accordance with examples as disclosed herein, a memory system may implement an adaptive rate for performing various wear leveling operations, such as an adaptive rate for performing wear leveling evaluations, or an adaptive rate for performing wear leveling data transfers, or some combination, among other examples. For example, a memory system may initially (e.g., as a default) perform wear leveling operations in accordance with a relatively slower rate, and may adjust (e.g., accelerate) wear leveling operations based on detecting a relatively greater demand to perform wear leveling operations. In some such examples, wear leveling operations may be capped at a rate (e.g., a maximum rate), which may limit a degradation of memory system performance while performing wear leveling operations (e.g., supporting a threshold level of performance even when wear leveling is performed at a relatively high rate). As wear distribution improves (e.g., due to performing wear leveling operations at a relatively high rate), the memory system may adjust (e.g., decelerate) wear leveling operations to improve an ability of the memory system to support other operations (e.g., access operations commanded by a host system, other background operations). Thus, the described techniques for performing wear leveling operations in accordance with an adaptive rate may be implemented to mitigate adverse effects associated with a relatively higher rate (e.g., a sudden burst) of wear leveling operations, improving a balance between a deceleration (e.g., throttling) of wear leveling activity to improve throughput or reduce power consumption of a memory system and an acceleration of wear leveling activity where favorable to support a threshold of wear distribution among memory cells of the memory system.

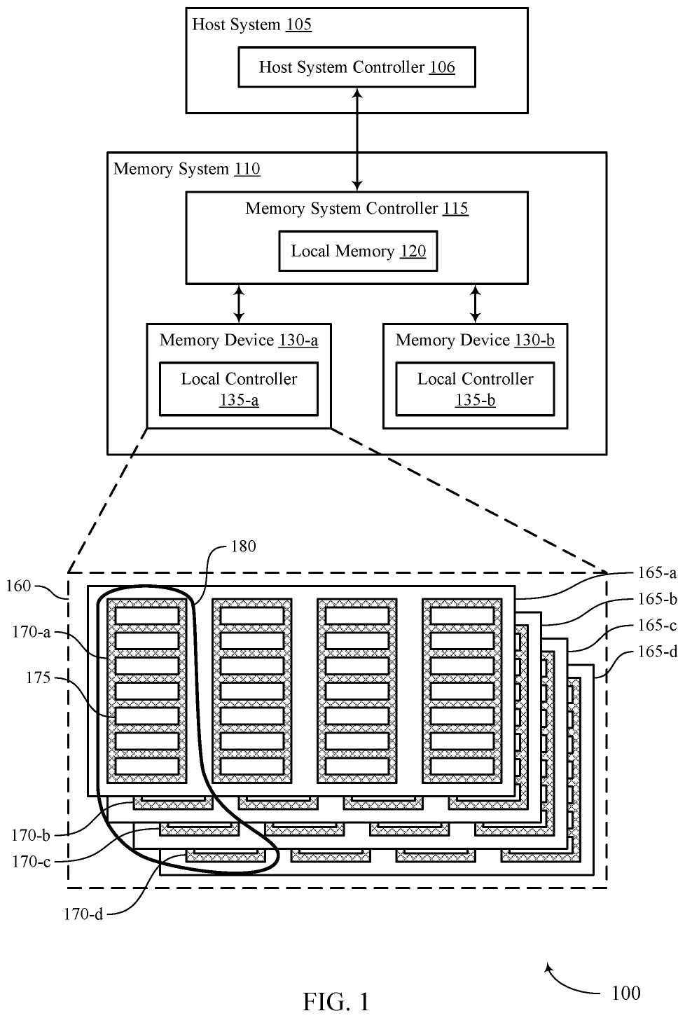

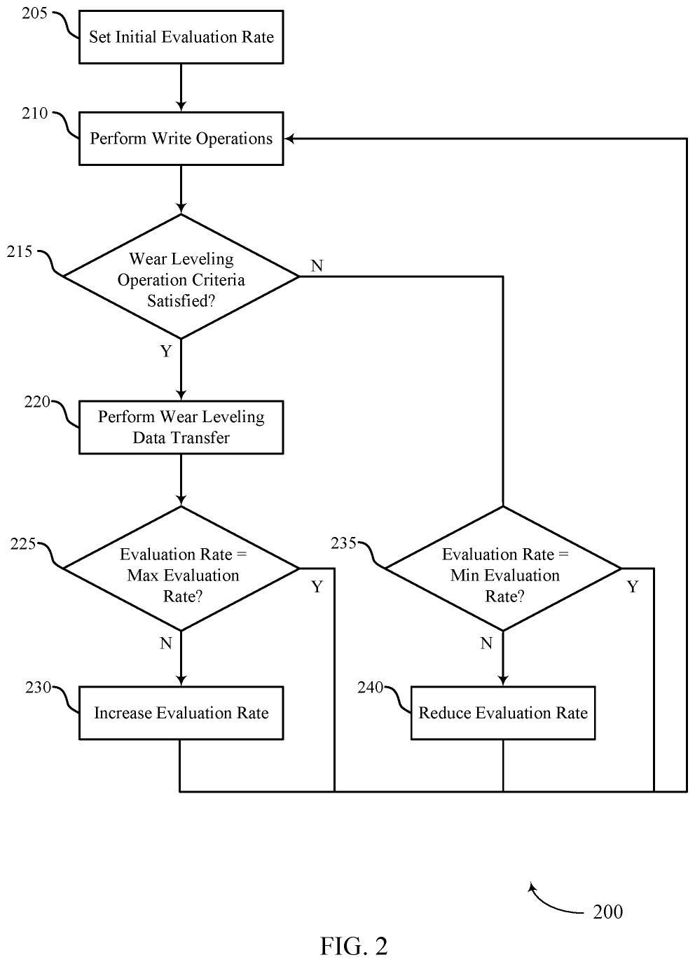

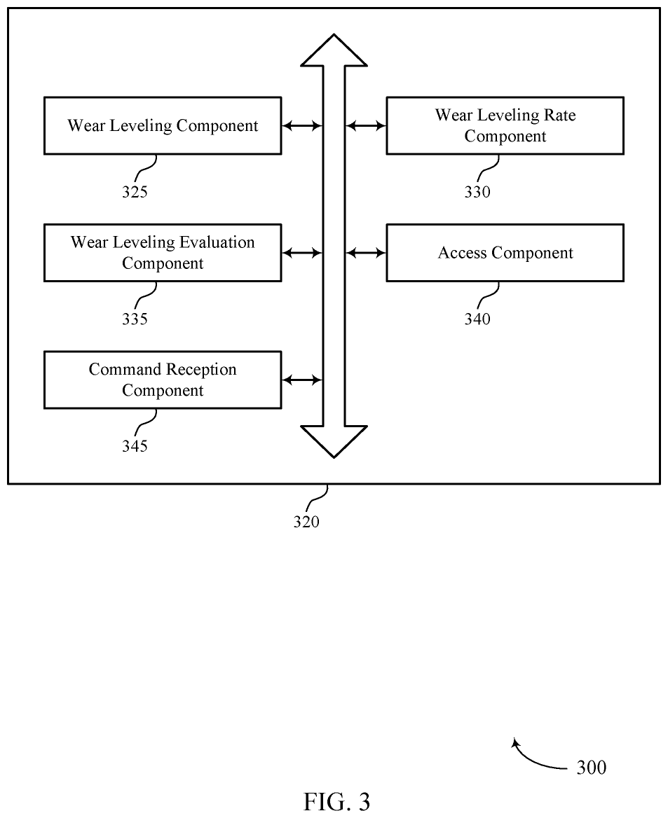

Features of the disclosure are initially described in the context of systems, devices, and circuits with reference to FIG. 1. Features of the disclosure are described in the context of a process flow for performing adaptive wear leveling for a memory system with reference to FIG. 2. These and other features of the disclosure are further illustrated by and described in the context of a block diagram and flowcharts that relate to adaptive wear leveling for a memory system with reference to FIGS. 3 through 6.

FIG. 1 illustrates an example of a system 100 that supports adaptive wear leveling for a memory system in accordance with examples as disclosed herein. The system 100 includes a host system 105 coupled with a memory system 110.

A memory system 110 may be or include any device or collection of devices, where the device or collection of devices includes at least one memory array. For example, a memory system 110 may be or include a Universal Flash Storage (UFS) device, an embedded Multi-Media Controller (eMMC) device, a flash device, a universal serial bus (USB) flash device, a secure digital (SD) card, a solid-state drive (SSD), a hard disk drive (HDD), a dual in-line memory module (DIMM), a small outline DIMM (SO-DIMM), or a non-volatile DIMM (NVDIMM), among other possibilities.

The system 100 may be included in a computing device such as a desktop computer, a laptop computer, a network server, a mobile device, a vehicle (e.g., airplane, drone, train, automobile, or other conveyance), an Internet of Things (IoT) enabled device, an embedded computer (e.g., one included in a vehicle, industrial equipment, or a networked commercial device), or any other computing device that includes memory and a processing device.

The system 100 may include a host system 105, which may be coupled with the memory system 110. In some examples, this coupling may include an interface with a host system controller 106, which may be an example of a controller or control component configured to cause the host system 105 to perform various operations in accordance with examples as described herein. The host system 105 may include one or more devices and, in some cases, may include a processor chipset and a software stack executed by the processor chipset. For example, the host system 105 may include an application configured for communicating with the memory system 110 or a device therein. The processor chipset may include one or more cores, one or more caches (e.g., memory local to or included in the host system 105), a memory controller (e.g., NVDIMM controller), and a storage protocol controller (e.g., peripheral component interconnect express (PCIe) controller, serial advanced technology attachment (SATA) controller). The host system 105 may use the memory system 110, for example, to write data to the memory system 110 and read data from the memory system 110. Although one memory system 110 is shown in FIG. 1, the host system 105 may be coupled with any quantity of memory systems 110.

The host system 105 may be coupled with the memory system 110 via at least one physical host interface. The host system 105 and the memory system 110 may, in some cases, be configured to communicate via a physical host interface using an associated protocol (e.g., to exchange or otherwise communicate control, address, data, and other signals between the memory system 110 and the host system 105). Examples of a physical host interface may include, but are not limited to, a SATA interface, a UFS interface, an eMMC interface, a PCIe interface, a USB interface, a Fiber Channel interface, a Small Computer System Interface (SCSI), a Serial Attached SCSI (SAS), a Double Data Rate (DDR) interface, a DIMM interface (e.g., DIMM socket interface that supports DDR), an Open NAND Flash Interface (ONFI), and a Low Power Double Data Rate (LPDDR) interface. In some examples, one or more such interfaces may be included in or otherwise supported between a host system controller 106 of the host system 105 and a memory system controller 115 of the memory system 110. In some examples, the host system 105 may be coupled with the memory system 110 (e.g., the host system controller 106 may be coupled with the memory system controller 115) via a respective physical host interface for each memory device 130 included in the memory system 110, or via a respective physical host interface for each type of memory device 130 included in the memory system 110.

The memory system 110 may include a memory system controller 115 and one or more memory devices 130. A memory device 130 may include one or more memory arrays of any type of memory cells (e.g., non-volatile memory cells, volatile memory cells, or any combination thereof). Although two memory devices 130-a and 130-b are shown in the example of FIG. 1, the memory system 110 may include any quantity of memory devices 130. Further, if the memory system 110 includes more than one memory device 130, different memory devices 130 within the memory system 110 may include the same or different types of memory cells.

The memory system controller 115 may be coupled with and communicate with the host system 105 (e.g., via the physical host interface) and may be an example of a controller or control component configured to cause the memory system 110 to perform various operations in accordance with examples as described herein. The memory system controller 115 may also be coupled with and communicate with memory devices 130 to perform operations such as reading data, writing data, erasing data, or refreshing data at a memory device 130—among other such operations—which may generically be referred to as access operations. In some cases, the memory system controller 115 may receive commands from the host system 105 and communicate with one or more memory devices 130 to execute such commands (e.g., at memory arrays within the one or more memory devices 130). For example, the memory system controller 115 may receive commands or operations from the host system 105 and may convert the commands or operations into instructions or appropriate commands to achieve the desired access of the memory devices 130. In some cases, the memory system controller 115 may exchange data with the host system 105 and with one or more memory devices 130 (e.g., in response to or otherwise in association with commands from the host system 105). For example, the memory system controller 115 may convert responses (e.g., data packets or other signals) associated with the memory devices 130 into corresponding signals for the host system 105.

The memory system controller 115 may be configured for other operations associated with the memory devices 130. For example, the memory system controller 115 may execute or manage operations such as wear-leveling operations, garbage collection operations, error control operations such as error-detecting operations or error-correcting operations, encryption operations, caching operations, media management operations, background refresh, health monitoring, and address translations between logical addresses (e.g., logical block addresses (LBAs)) associated with commands from the host system 105 and physical addresses (e.g., physical block addresses) associated with memory cells within the memory devices 130.

The memory system controller 115 may include hardware such as one or more integrated circuits or discrete components, a buffer memory, or a combination thereof. The hardware may include circuitry with dedicated (e.g., hard-coded) logic to perform the operations ascribed herein to the memory system controller 115. The memory system controller 115 may be or include a microcontroller, special purpose logic circuitry (e.g., a field programmable gate array (FPGA), an application specific integrated circuit (ASIC), a digital signal processor (DSP)), or any other suitable processor or processing circuitry.

The memory system controller 115 may also include a local memory 120. In some cases, the local memory 120 may include read-only memory (ROM) or other memory that may store operating code (e.g., executable instructions) executable by the memory system controller 115 to perform functions ascribed herein to the memory system controller 115. In some cases, the local memory 120 may additionally or alternatively include static random access memory (SRAM) or other memory that may be used by the memory system controller 115 for internal storage or calculations, for example, related to the functions ascribed herein to the memory system controller 115. Additionally, or alternatively, the local memory 120 may serve as a cache for the memory system controller 115. For example, data may be stored in the local memory 120 if read from or written to a memory device 130, and the data may be available within the local memory 120 for subsequent retrieval for or manipulation (e.g., updating) by the host system 105 (e.g., with reduced latency relative to a memory device 130) in accordance with a cache policy.

Although the example of the memory system 110 in FIG. 1 has been illustrated as including the memory system controller 115, in some cases, a memory system 110 may not include a memory system controller 115. For example, the memory system 110 may additionally, or alternatively, rely on an external controller (e.g., implemented by the host system 105) or one or more local controllers 135, which may be internal to memory devices 130, respectively, to perform the functions ascribed herein to the memory system controller 115. In general, one or more functions ascribed herein to the memory system controller 115 may, in some cases, be performed instead by the host system 105, a local controller 135, or any combination thereof. In some cases, a memory device 130 that is managed at least in part by a memory system controller 115 may be referred to as a managed memory device. An example of a managed memory device is a managed NAND (MNAND) device.

A memory device 130 may include one or more arrays of non-volatile memory cells. For example, a memory device 130 may include NAND (e.g., NAND flash) memory, ROM, phase change memory (PCM), self-selecting memory, other chalcogenide-based memories, ferroelectric random access memory (RAM) (FeRAM), magneto RAM (MRAM), NOR (e.g., NOR flash) memory, Spin Transfer Torque (STT)-MRAM, conductive bridging RAM (CBRAM), resistive random access memory (RRAM), oxide based RRAM (OxRAM), electrically erasable programmable ROM (EEPROM), or any combination thereof. Additionally, or alternatively, a memory device 130 may include one or more arrays of volatile memory cells. For example, a memory device 130 may include RAM memory cells, such as dynamic RAM (DRAM) memory cells and synchronous DRAM (SDRAM) memory cells.

In some examples, a memory device 130 may include (e.g., on a same die or within a same package) a local controller 135, which may execute operations on one or more memory cells of the respective memory device 130. A local controller 135 may operate in conjunction with a memory system controller 115 or may perform one or more functions ascribed herein to the memory system controller 115. For example, as illustrated in FIG. 1, a memory device 130-a may include a local controller 135-a and a memory device 130-b may include a local controller 135-b.

In some cases, a memory device 130 may be or include a NAND device (e.g., NAND flash device). A memory device 130 may be or include a memory die 160. For example, in some cases, a memory device 130 may be a package that includes one or more dies 160. A die 160 may, in some examples, be a piece of electronics-grade semiconductor cut from a wafer (e.g., a silicon die cut from a silicon wafer). Each die 160 may include one or more planes 165, and each plane 165 may include a respective set of blocks 170, where each block 170 may include a respective set of pages 175, and each page 175 may include a set of memory cells.

In some cases, a NAND memory device 130 may include memory cells configured to each store one bit of information, which may be referred to as single level cells (SLCs). Additionally, or alternatively, a NAND memory device 130 may include memory cells configured to each store multiple bits of information, which may be referred to as multi-level cells (MLCs) if configured to each store two bits of information, as tri-level cells (TLCs) if configured to each store three bits of information, as quad-level cells (QLCs) if configured to each store four bits of information, or more generically as multiple-level memory cells. Multiple-level memory cells may provide greater density of storage relative to SLC memory cells but may, in some cases, involve narrower read or write margins or greater complexities for supporting circuitry.

In some cases, planes 165 may refer to groups of blocks 170, and in some cases, concurrent operations may be performed on different planes 165. For example, concurrent operations may be performed on memory cells within different blocks 170 so long as the different blocks 170 are in different planes 165. In some cases, an individual block 170 may be referred to as a physical block, and a virtual block 180 may refer to a group of blocks 170 within which concurrent operations may occur. For example, concurrent operations may be performed on blocks 170-a, 170-b, 170-c, and 170-d that are within planes 165-a, 165-b, 165-c, and 165-d, respectively, and blocks 170-a, 170-b, 170-c, and 170-d may be collectively referred to as a virtual block 180. In some cases, a virtual block may include blocks 170 from different memory devices 130 (e.g., including blocks in one or more planes of memory device 130-a and memory device 130-b). In some cases, the blocks 170 within a virtual block may have the same block address within their respective planes 165 (e.g., block 170-a may be “block 0” of plane 165-a, block 170-b may be “block 0” of plane 165-b, and so on). In some cases, performing concurrent operations in different planes 165 may be subject to one or more restrictions, such as concurrent operations being performed on memory cells within different pages 175 that have the same page address within their respective planes 165 (e.g., related to command decoding, page address decoding circuitry, or other circuitry being shared across planes 165).

In some cases, a block 170 may include memory cells organized into rows (pages 175) and columns (e.g., strings, not shown). For example, memory cells in a same page 175 may share (e.g., be coupled with) a common word line, and memory cells in a same string may share (e.g., be coupled with) a common digit line (which may alternatively be referred to as a bit line).

For some NAND architectures, memory cells may be read and programmed (e.g., written) at a first level of granularity (e.g., at the page level of granularity) but may be erased at a second level of granularity (e.g., at the block level of granularity). That is, a page 175 may be the smallest unit of memory (e.g., set of memory cells) that may be independently programmed or read (e.g., programed or read concurrently as part of a single program or read operation), and a block 170 may be the smallest unit of memory (e.g., set of memory cells) that may be independently erased (e.g., erased concurrently as part of a single erase operation). Further, in some cases, NAND memory cells may be erased before they can be re-written with new data. Thus, for example, a used page 175 may, in some cases, not be updated until the entire block 170 that includes the page 175 has been erased.

In some cases, to update some data within a block 170 while retaining other data within the block 170, the memory device 130 may copy the data to be retained to a new block 170 and write the updated data to one or more remaining pages of the new block 170. The memory device 130 (e.g., the local controller 135) or the memory system controller 115 may mark or otherwise designate the data that remains in the old block 170 as invalid or obsolete and may update a logical-to-physical (L2P) mapping table to associate the logical address (e.g., LBA) for the data with the new, valid block 170 rather than the old, invalid block 170. In some cases, such copying and remapping may be performed instead of erasing and rewriting the entire old block 170 due to latency or wearout considerations, for example. In some cases, one or more copies of an L2P mapping table may be stored within the memory cells of the memory device 130 (e.g., within one or more blocks 170 or planes 165) for use (e.g., reference and updating) by the local controller 135 or memory system controller 115.

In some cases, a memory system controller 115 or a local controller 135 may perform operations (e.g., as part of one or more media management algorithms) for a memory device 130, such as wear leveling, background refresh, garbage collection, scrub, block scans, health monitoring, or others, or any combination thereof. For example, within a memory device 130, a block 170 may have some pages 175 containing valid data and some pages 175 containing invalid data. To avoid waiting for all of the pages 175 in the block 170 to have invalid data in order to erase and reuse the block 170, an algorithm referred to as “garbage collection” may be invoked to allow the block 170 to be erased and released as a free block for subsequent write operations. Garbage collection may refer to a set of media management operations that include, for example, selecting a block 170 that contains valid and invalid data, selecting pages 175 in the block that contain valid data, copying the valid data from the selected pages 175 to new locations (e.g., free pages 175 in another block 170), marking the data in the previously selected pages 175 as invalid, and erasing the selected block 170. As a result, the quantity of blocks 170 that have been erased may be increased such that more blocks 170 are available to store subsequent data (e.g., data subsequently received from the host system 105).

In some cases, a memory system 110 may utilize a memory system controller 115 to provide a managed memory system that may include, for example, one or more memory arrays and related circuitry combined with a local (e.g., on-die or in-package) controller (e.g., local controller 135). An example of a managed memory system is a managed NAND (MNAND) system.

In some cases, memory cells of a memory system 110 (e.g., of a memory device 130, of local memory 120) may degrade over an operable life of the memory system 110, which may impair an ability of the memory cells to be written to, to maintain state over time, or to be read from, or a combination thereof. To extend an operable life of the memory system 110, the memory system 110 (e.g., a memory system controller 115, a local controller 135) may be configured to implement wear leveling techniques to mitigate adverse effects associated with certain memory cells degrading at different rates (e.g., more quickly) than others, which may distribute degradation more evenly across memory cells of the memory system 110 and maintain a more consistent performance profile throughout the life of the memory system 110. In some examples, wear leveling techniques may involve a background process of moving data that is modified or otherwise accessed relatively infrequently to memory cells with relatively higher degradation, which may reduce an accumulation of degradation by those memory cells with relatively greater degradation, and make memory cells with relatively lower degradation available for more frequent accessing.

In some examples, degradation of memory cells may be associated with (e.g., may be a result of, may be accelerated by) access operations performed on the memory cells. Degradation of NAND memory cells, for example, may be associated with relatively high voltages applied to the memory cells during program operations, during erase operations, during other operations, or various combinations thereof. In some examples, the memory system 110 may be configured to monitor respective quantities of access operations performed on memory cells, or sets thereof (e.g., planes 165, blocks 170, pages 175), as an estimate of degradation of the memory cells, or the sets thereof. In some memory architectures, such as NAND memory architectures, such monitoring may include tracking a quantity of program/erase cycles (PECs), which may refer to a quantity of cycles for which a memory cell, or set thereof, has been programmed and erased (e.g., due to a correlation between such cycles and a level of degradation of NAND memory cells). Thus, the memory system 110 may monitor an accumulation of PECs as at least part of an estimate of memory cell degradation, in which case a relatively higher quantity of PECs may indicate a likelihood of relatively greater degradation. A memory system 110 may track PEC cycles by counting a quantity of write operations on a set of one or more memory cells, or by counting a quantity of erase operations on a set of one or more memory cells which, in some examples, may be largely equivalent (e.g., due to the nature of erasing NAND memory cells before writing new data to the NAND memory cells). In various other examples, the memory system 110 may implement other techniques of counting respective access operations, or other evaluations or combination thereof, for sets of one or more memory cells as a proxy for degradation level.

In some cases, PECs may be associated with data migrations (e.g., data transfers) within a memory device 130 or between memory devices 130, such as a movement of data from memory cells supporting a first storage density to memory cells supporting a second storage density. For example, a memory system 110 may receive data to be written from a host system 105, and may initially store the data in an SLC cache (e.g., an SLC queue, of a memory device 130, of a local memory 120, to leverage a relatively faster write operation for higher throughput). The data may then be migrated from (e.g., read from) the SLC cache to a multiple level cell storage array (e.g., a MLC array, a TLC array, a QLC array, of a same memory device 130 or a different memory device 130, to leverage relatively higher storage density). In some examples, a memory system 110 may count a quantity of such data migrations to at least partially support an estimate of degradation of the related memory cells (e.g., of the SLC cache, of the multiple level cell storage array).

In some cases, sets of memory cells of the memory system 110 may experience different rates of degradation, such as when different sets of memory cells accumulate different quantities of PECs. For example, a distribution of PEC counts across the memory cells may be relatively varied (e.g., associated with relatively large disparities of PEC counts between sets of memory cells), resulting in a relatively uneven degradation across the memory cells. In some examples, an uneven degradation of memory cells may decrease an operable life of the memory system 110 due to certain memory cells degrading beyond a threshold (e.g., a failure threshold, an operability threshold) and no longer being available or reliable for data storage. In some cases, a more-uniform distribution of PEC counts across the memory cells (e.g., with relatively minor variability) may result in relatively even physical degradation across the memory cells, thereby extending the life of the memory system 110 (e.g., supporting a rated storage capacity for a longer operable duration).

To prolong an operable lifetime of the memory system 110, the memory system 110 may implement wear leveling operations (e.g., static wear leveling (SWL)) to reduce differences of PEC counts between sets of memory cells of the memory system 110. In some examples, wear leveling operations may identify memory cells associated with data that is accessed (e.g., written, read, erased) relatively infrequently, and transfer the data to relatively frequently-accessed memory cells. For example, during a wear leveling data transfer, data stored in frequently-accessed memory cells may be replaced by infrequently-accessed data (e.g., from infrequently-accessed memory cells), which may be accompanied by data of frequently-accessed memory cells being written to the infrequently-accessed memory cells, or the frequently-accessed memory cells being erased (e.g., when the corresponding data is marked as invalid or otherwise no longer needed, to make them available for new data). Thus, the rate of degradation associated with the frequently-accessed memory cells may be reduced, while the rate of degradation associated with the infrequently-accessed memory cells may be increased (e.g., with more frequent programming and erasing), which may support a more uniform accumulation of physical degradation.

Wear leveling operations performed by a memory system 110 may involve various evaluation techniques, which may include the memory system 110 determining whether wear leveling criteria have been satisfied (e.g., whether a distribution of PEC counts has become too wide). For example, a wear leveling evaluation may determine whether to perform a wear leveling data transfer among one or more memory cells or sets of memory cells based on the quantity of PECs (e.g., the PEC count) experienced by the memory cells. In some examples, a wear leveling evaluation may include comparing the quantity of PECs of a set of memory cells to a threshold (e.g., an average quantity of PECs of a memory device 130 or multiple memory devices 130, a target quantity of PECs of a memory device 130 or multiple memory devices 130). In some implementations, wear leveling operations themselves may cause an incremental increase in degradation to memory cells of the memory system 110 (e.g., due to one or more incremental PECs associated with performing a data transfer). Thus, in some examples, at least some degree of PEC disparity among sets of memory cells may be permitted without performing a wear leveling data transfer (e.g., to avoid undue accumulation of degradation associated with wear leveling operations themselves).

Performing wear leveling operations may occupy resources (e.g., processing resources, signaling resources, power resources, write bandwidth) of the memory system 110, which may at least temporarily reduce an ability of the memory system 110 to perform other operations. For example, an allocation of resources to support wear leveling evaluations, or wear leveling data transfers, or both may decrease throughput or increase latency for access operations commanded by a host system 105 (e.g., due to resources allocated to wear leveling being unavailable for supporting access operations). In some examples, wear leveling may be associated with a relative spike in latency or reduction in throughput, such as when a large quantity of memory cells become candidates for wear leveling data transfers in a short duration. Such circumstances may arise, for example, when some memory cells of the memory system 110 are written with relatively static data, such as an operating system or archival data, while other memory cells of the memory system 110 are written with relatively transient data, such as streaming data or other data that is written and discarded relatively frequently. In such examples, a relatively large quantity of memory cells may satisfy criteria to perform wear leveling data transfer within a short duration (e.g., memory cells written to without being modified or reset). Therefore, the memory system 110 may perform many concurrent or subsequent wear leveling data transfers within a short duration (e.g., in SWL bursts), occupying resources that may result in relatively high latency or low throughput (e.g., for access operations by a host system 105).

Some implementations of the memory system 110, including implementations in accordance with a zoned namespace (ZNS) architecture, may rely on or expect a threshold level of performance (e.g., a threshold latency, a threshold throughput, a threshold quality of service (QoS)) from the memory system 110, which may be impaired by background operations of the memory system 110 such as wear leveling operations. Thus, in some implementations, such as for the memory system 110 implemented in a ZNS architecture, increased latency or reduced throughput associated with bursts of wear leveling operations may impair the ability of a memory system 110 to support the threshold level of performance.

In accordance with examples as disclosed herein, the memory system 110 may implement an adaptive rate for performing various wear leveling operations, such as an adaptive rate for performing wear leveling evaluations, or an adaptive rate for performing wear leveling data transfers, or some combination, among other examples. In some examples, such techniques may be referred to as or otherwise include adaptive wear level checking (AWLC), and may provide various techniques to modulate a rate at which wear leveling operations are performed (e.g., by increasing or decreasing an amount of wear leveling based on how widely distributed PECs are among memory cells of the memory system 110). For example, the memory system 110 may begin with or default to performing wear leveling operations in accordance with a relatively slower rate, and may adjust (e.g., accelerate) wear leveling operations based on detecting a relatively greater demand to perform wear leveling operations. In some such examples, wear leveling operations may be capped at a maximum rate, which may limit a degradation of memory system 110 performance while performing wear leveling operations (e.g., supporting a threshold level of performance even when wear leveling is performed at a relatively high rate, reducing a likelihood that wear leveling impacts a data transfer rate with a host system 105). As wear distribution improves (e.g., due to performing wear leveling operations at a relatively high rate), the memory system 110 may adjust (e.g., decelerate) wear leveling operations, which improve an ability of the memory system to support other operations (e.g., access operations commanded by the host system 105, other background operations), or reduce power consumption, among other benefits.

Thus, the described techniques for performing wear leveling operations in accordance with an adaptive rate may be implemented to mitigate adverse effects that may be associated with a sudden burst of wear leveling operations. For example, such techniques may reduce or eliminate bursts of wear leveling evaluations or associated data transfers, and may reduce an amount of processing power involved with wear leveling by reducing a frequency of processor-intensive wear leveling evaluations. In some examples, the described techniques may be adapted based on workload of the memory system 110, such as an amount of access operations (e.g., read operations, write operations) being commanded by a host system 105. Moreover, the described techniques may increase a duration before migrating data of a given set of memory cells (e.g., of a block 170), which may increase a likelihood that the data is reset (e.g., marked as invalid and available for erasure) such that a wear leveling data transfer may no longer be needed on the set of memory cells. Thus, in accordance with these and other examples, the described techniques for adaptive wear leveling may improve a balance between a deceleration of wear leveling activity to improve throughput or reduce power consumption of the memory system 110 and an acceleration of wear leveling activity where favorable to support a threshold of wear distribution among memory cells of the memory system 110.

The system 100 may include any quantity of non-transitory computer readable media that support adaptive wear leveling for a memory system. For example, the host system 105 (e.g., a host system controller 106), the memory system 110 (e.g., a memory system controller 115), or a memory device 130 (e.g., a local controller 135) may include or otherwise may access one or more non-transitory computer readable media storing instructions (e.g., firmware, logic, code) for performing the functions ascribed herein to the host system 105, the memory system 110, or a memory device 130. For example, such instructions, if executed by the host system 105 (e.g., by a host system controller 106), by the memory system 110 (e.g., by a memory system controller 115), or by a memory device 130 (e.g., by a local controller 135), may cause the host system 105, the memory system 110, or the memory device 130 to perform associated functions as described herein.

FIG. 2 illustrates an example of process flow 200 that supports adaptive wear leveling for a memory system in accordance with examples as disclosed herein. The process flow 200 may be an example for implementing aspects or operations of a system 100 described with reference to FIG. 1. For example, the process flow 200 may illustrate examples of operations that may be performed by a memory system 110 or a component thereof (e.g., a memory system controller 115, a local controller 135).

A memory system 110 that performs the process flow 200 may implement wear leveling operations to support a more uniform distribution of physical degradation across memory cells of the memory system. In some cases, however, a relatively large quantity of memory cells of the memory system 110 may become candidates for wear leveling data transfer within a short duration. The process flow 200 illustrates an example of techniques for adapting a rate of wear leveling operations (e.g., how frequently wear leveling operations are performed) based on an indication of a wear condition of the memory system 100 (e.g., a degradation distribution, conditions for performing wear leveling data transfers), which may reduce adverse effects to performance of the memory system 100 that might otherwise occur from performing bursts of wear leveling operations in such scenarios. For example, the memory system 110 may increase an evaluation rate (e.g., to a maximum rate) or decrease an evaluation rate (e.g., to a minimum rate) to support degradation uniformity of the memory system 110 while also supporting a threshold level of performance (e.g., a threshold throughput performance, a threshold latency performance).

At 205, the memory system 110 may set an initial evaluation rate (e.g., a first rate of wear leveling evaluation, a default evaluation rate). In some examples, the initial evaluation rate may be a minimum evaluation rate (e.g., a maximum adaptive check period), such as a minimum configured evaluation rate of the memory system 110. In some examples, the evaluation rate may be associated with a quantity of access operations performed at the memory system 110. For example, the initial evaluation rate may be associated with (e.g., set to) a quantity of 256 migrations (e.g., from an SLC cache to a multiple-level cell array), such that the memory system 110 is configured to perform a wear leveling evaluation after performing 256 migrations. Setting an evaluation rate in terms of access operations, rather than time (e.g., a clock time), may enable the memory system 110 to account for access variations, such as when access operations occur (e.g., as commanded by a host system 105) at different rates, or to reduce or prevent wear leveling operations in some circumstances (e.g., to inhibit wear leveling evaluations during periods without migrations, during idle time, during read-only operations, or during durations over which no write data is received), which may support relatively longer durations between the wear leveling evaluations. Further, using a quantity of migrations to establish an evaluation rate may increase a likelihood that at least some memory cells may be reset (e.g., marked as invalid or otherwise available for erasure), which may avoid performing a transfer of such data.

At 210, the memory system 110 may perform write operations (e.g., in accordance with the configured evaluation rate, such as the initial evaluation rate of 205 or an adapted evaluation rate). In some examples, the write operations of 210 may include a quantity of migrations, where data is transferred from memory cells of a first storage density (e.g., an SLC cache) to memory cells of a second storage density (e.g., a multiple-level cell array). For example, a data segment associated with a write operation may be written to four SLCs of an SLC queue then combined and stored to one QLC of the QLC storage. In some cases, the write operations of 210 may be performed in response to commands (e.g., write commands) received from a host system 105. After performing the write operations of 210, the process flow 200 may proceed to 215.

At 215, the memory system 110 may evaluate whether a wear leveling operation criteria has been satisfied (e.g., whether memory cells of the memory system 110 are above or below a threshold distribution of degradation). For example, if a relatively wide distribution of degradation is observed, the process flow may proceed to 220, and if a relatively narrow distribution is observed, the process flow may proceed to 235. In some examples, the evaluation of 215 may include the memory system 110 comparing a PEC count of a set of one or more memory cells (e.g., of a block 170) to a threshold (e.g., an average value or a target value of PEC counts across the memory cells, among other examples). For example, if a lowest-mapped PEC satisfies a threshold (e.g., is less than a threshold, such as target block PEC), which may indicate a relatively wide distribution of degradation at the memory system 110, the process flow may proceed to 220 (e.g., to perform one or more wear leveling data transfers). If a lowest-mapped PEC does not satisfy the threshold (e.g., is greater than a threshold), which may indicate a relatively narrow distribution of degradation, the process flow 200 may proceed to 235 (e.g., refraining from performing one or more wear leveling data transfers).

At 220, the memory system 110 may perform one or more wear leveling data transfers. The wear leveling data transfers may include identifying a set of one or more memory cells (e.g., memory cells of a block 170) with a PEC count that is less than threshold PEC value and transferring data from the set of memory cells to one or more memory cells in another portion of the memory system. For example, the wear leveling data transfers may transfer relatively static data, associated with memory cells having relatively low PEC counts, to memory cells that have been used to store relatively transient data, having relatively high PEC counts. In some cases, performing wear leveling data transfers may include reading data from a first block of memory cells associated with a lowest quantity of PECs and writing the information to a second block of memory cells different than the first block of memory cells.

At 225 (e.g., based on performing a wear leveling data transfer or otherwise satisfying corresponding criteria), the memory system 110 may determine whether the configured evaluation rate (e.g., the initial evaluation rate of 205 or other configured evaluation rate) is equal to a maximum evaluation rate (e.g., a minimum adaptive check period), which may be used to determine whether to increase the evaluation rate (e.g., to reduce the wear leveling check period). For example, when the evaluation rate is equivalent to the initial evaluation rate associated with performing 256 migrations (e.g., a quantity of migrations between wear leveling evaluations of 215), the evaluation rate may be compared to a maximum evaluation rate associated with performing 8 migrations. In such an example (e.g., with 256 migrations being different than 8 migrations), the process flow 200 may proceed to 230 (e.g., to increase the evaluation rate). In other examples (e.g., when the configured evaluation rate is equal to the maximum evaluation rate), the process flow may return to 210 (e.g., to continue performing write operations at the same configured evaluation rate, refraining from increasing the evaluation rate). In some examples, the maximum evaluation rate may be configured to support a threshold quality of service (e.g., by limiting a frequency at which wear leveling operations are performed to limit an allocation of resources to wear leveling operations).

At 230, the memory system 110 may increase the evaluation rate to a new evaluation rate, such that wear leveling operations (e.g., wear leveling evaluations of 215, wear leveling data transfers of 220) may be performed more frequently. In some examples, the new evaluation rate may be determined by multiplying the configured evaluation rate (e.g., the initial evaluation rate, an evaluation rate associated with the write operations of 210 or proceeding to the operations of 215) by an adaptive adjust rate, which may be a ratio value (e.g., a value between 0 and 1) or other multiplier. For example, when the configured evaluation rate is equivalent to the minimum evaluation rate associated with 256 migrations, the evaluation rate may be increased by multiplying the configured evaluation rate by an adaptive adjust rate of 0.5 (e.g., dividing the quantity of migrations in half, multiplying the evaluation rate by two) to establish a new configured evaluation rate associated with 128 migrations. After such an increase, the process flow 200 may return to 210 to perform write operations in accordance with the increased evaluation rate (e.g., proceeding from 210 to 215 after performing 128 migrations). If criteria for performing wear leveling operations of 220 continue to be satisfied, the evaluation rate may continue to be increased at further instances of the operations of 230 (e.g., to 64 migrations, then 32 migrations, and so on), until reaching the maximum evaluation rate (e.g., associated with the minimum of 8 migrations, for which the conditions of 225 may be met), in which case further evaluations may be performed each 8 migrations (e.g., until the criteria for wear leveling operations of 215 are no longer satisfied, after which the process flow 200 may proceed to 235).

At 235 (e.g., having determined that the wear leveling operation criteria are not satisfied), the memory system 110 may determine whether the configured evaluation rate (e.g., the initial evaluation rate of 205 or other configured evaluation rate) is equal to the minimum evaluation rate, which may be used to determine whether to decrease the evaluation rate (e.g., to increase the wear leveling check period). For example, when the configured evaluation rate is equivalent to the maximum evaluation rate associated with performing 8 migrations, the evaluation rate may be compared to the minimum evaluation rate associated with performing 256 migrations. In such an example (e.g., with 8 migrations being different than 256 migrations), the process flow 200 may proceed to 240 (e.g., to reduce the evaluation rate). In other examples (e.g., when the configured evaluation rate is equal to the minimum evaluation rate), the process flow may return to 210 (e.g., to continue performing write operations at the same configured evaluation rate, refraining from decreasing the evaluation rate).

At 240, the memory system 110 may decrease the evaluation rate to a new evaluation rate, such that wear leveling operations (e.g., wear leveling evaluations of 215, wear leveling data transfers of 220) may be performed less frequently. In some examples, the new evaluation rate may be determined by multiplying the configured evaluation rate by an adaptive adjust rate, which may be the same as the adaptive adjust rate applied at 230 (e.g., but applied as a division rather than a multiplication) or different than the adaptive adjust rate applied at 230. For example, when the configured evaluation rate is equivalent to the maximum evaluation rate associated with 8 migrations, the evaluation rate may be reduced by dividing the configured evaluation rate by an adaptive adjust rate of 0.5 (e.g., multiplying the quantity of migrations by two, dividing the evaluation rate in half) to establish a new configured evaluation rate associated with 16 migrations. After such a decrease, the process flow 200 may return to 210 to perform write operations in accordance with the reduced evaluation rate (e.g., proceeding from 210 to 215 after performing 16 migrations). If criteria for performing wear leveling operations of 220 continue to be not satisfied, the evaluation rate may continue to be decreased at further instances of the operations of 240 (e.g., to 32 migrations, then 64 migrations, and so on), until reaching the minimum evaluation rate (e.g., associated with 256 migrations, for which the conditions of 235 may be met), in which case further evaluations may be performed each 256 migrations (e.g., until the criteria for wear leveling operations of 215 are satisfied, after which the process flow 200 may proceed to 225).

Adaptively adjusting an evaluation rate for wear leveling operations, such as the example of techniques illustrated by the process flow 200, may allow the memory system 110 to increase or decrease the frequency of performing wear leveling operations based on the wear leveling demand of the memory system 110. For example, through successive iterations through the process flow 200, the evaluation rate may be gradually reduced until reaching the minimum evaluation rate, or gradually increased until reaching the maximum evaluation rate. By implementing such techniques, the memory system 110 may reduce the amount of processing power allocated to wear leveling operations in some conditions by reducing the number of processor-intensive operations (e.g., wear leveling evaluations), and accelerate wear leveling operations in some other conditions to maintain PEC counts within an allowed range.

FIG. 3 shows a block diagram 300 of a memory system 320 that supports adaptive wear leveling in accordance with examples as disclosed herein. The memory system 320 may be an example of aspects of a memory system as described with reference to FIGS. 1 and 2. The memory system 320, or various components thereof, may be an example of means for performing various aspects of adaptive wear leveling for a memory system as described herein. For example, the memory system 320 may include a wear leveling component 325, a wear leveling rate component 330, a wear leveling evaluation component 335, an access component 340, a command reception component 345, or any combination thereof. Each of these components may communicate, directly or indirectly, with one another (e.g., via one or more buses).

The wear leveling component 325 may be configured as or otherwise support a means for performing a first wear leveling operation at a memory system based at least in part on performing a first quantity of write operations at the memory system. The wear leveling rate component 330 may be configured as or otherwise support a means for determining a second quantity of write operations based at least in part on performing the first wear leveling operation. The wear leveling evaluation component 335 may be configured as or otherwise support a means for determining whether to perform a second wear leveling operation at the memory system based at least in part on performing the second quantity of write operations at the memory system.

In some examples, the second quantity of write operations may be less than the first quantity of write operations.

In some examples, the wear leveling evaluation component 335 may be configured as or otherwise support a means for determining whether to perform the first wear leveling operation in accordance with a first rate of evaluation that is associated with the first quantity of write operations, and performing the first wear leveling operation may be based at least in part on determining to perform the first wear leveling operation. In some examples, the wear leveling evaluation component 335 may be configured as or otherwise support a means for determining whether to perform the second wear leveling operation in accordance with a second rate of evaluation, greater than the first rate of evaluation, that associated with the second quantity of write operations.

In some examples, the command reception component 345 may be configured as or otherwise support a means for receiving a first set of one or more commands from a host system. In some examples, the access component 340 may be configured as or otherwise support a means for performing the first quantity of write operations based at least in part on the first set of one or more commands from the host system. In some examples, the command reception component 345 may be configured as or otherwise support a means for receiving a second set of one or more commands from the host system. In some examples, the access component 340 may be configured as or otherwise support a means for performing the second quantity of write operations based at least in part on the second set of one or more commands from the host system.

In some examples, write operations of the first quantity of write operations and write operations of the second quantity of write operations may be associated with migrating data from memory cells of the memory system that are associated with a first storage density to memory cells of the memory system that are associated with a second storage density.

In some examples, the wear leveling evaluation component 335 may be configured as or otherwise support a means for determining that a lowest quantity of program/erase cycles associated with a plurality of blocks of memory cells of the memory system satisfies a threshold, and performing the first wear leveling operation at a memory system may be based at least in part on determining that the lowest quantity of program/erase cycles satisfies the threshold.

In some examples, to support performing the first wear leveling operation, the wear leveling component 325 may be configured as or otherwise support a means for reading information from a first block of memory cells associated with a lowest quantity of program/erase cycles. In some examples, to support performing the first wear leveling operation, the wear leveling component 325 may be configured as or otherwise support a means for writing the information to a second block of memory cells different than the first block of memory cells.

In some examples, the wear leveling component 325 may be configured as or otherwise support a means for performing the second wear leveling operation at the memory system based at least in part on determining to perform the second wear leveling operation. In some examples, the wear leveling rate component 330 may be configured as or otherwise support a means for determining a third quantity of write operations at the memory system, less than the second quantity of write operations, based at least in part on determining to perform the second wear leveling operation. In some examples, the wear leveling evaluation component 335 may be configured as or otherwise support a means for determining whether to perform a third wear leveling operation at the memory system based at least in part on performing the third quantity of write operations at the memory system.

In some examples, the wear leveling component 325 may be configured as or otherwise support a means for refraining from performing the second wear leveling operation at the memory system based at least in part on determining to not perform the second wear leveling operation. In some examples, the wear leveling rate component 330 may be configured as or otherwise support a means for determining a third quantity of write operations at the memory system, greater than the second quantity of write operations, based at least in part on determining to not perform the second wear leveling operation. In some examples, the wear leveling evaluation component 335 may be configured as or otherwise support a means for determining whether to perform a third wear leveling operation at the memory system based at least in part on performing the third quantity of write operations at the memory system.

In some examples, the access component 340 may be configured as or otherwise support a means for performing a first quantity of write operations at a memory system. In some examples, the wear leveling evaluation component 335 may be configured as or otherwise support a means for determining to refrain from performing a first wear leveling operation at the memory system based at least in part on performing the first quantity of write operations at the memory system. In some examples, the access component 340 may be configured as or otherwise support a means for performing a second quantity of write operations at the memory system. In some examples, the wear leveling evaluation component 335 may be configured as or otherwise support a means for determining whether to perform a second wear leveling operation at the memory system based at least in part on determining to refrain from performing the first wear leveling operation and performing the second quantity of write operations at the memory system.

In some examples, the second quantity of write operations may be greater than the first quantity of write operations.

In some examples, the wear leveling evaluation component 335 may be configured as or otherwise support a means for determining whether to perform the first wear leveling operation in accordance with a first rate of evaluation that is associated with the first quantity of write operations, and determining to refrain from performing the first wear leveling operation may be based at least in part on the determining whether to perform the first wear leveling operation. In some examples, the wear leveling evaluation component 335 may be configured as or otherwise support a means for determining whether to perform the second wear leveling operation in accordance with a second rate of evaluation, less than the first rate of evaluation, that is associated with the second quantity of write operations.

In some examples, the command reception component 345 may be configured as or otherwise support a means for receiving a first set of one or more commands from a host system, and performing the first quantity of write operations may be based at least in part on the first set of one or more commands from the host system. In some examples, the command reception component 345 may be configured as or otherwise support a means for receiving a second set of one or more commands from the host system, and performing the second quantity of write operations may be based at least in part on the second set of one or more commands from the host system.

In some examples, write operations of the first quantity of write operations and of the second quantity of write operations may be associated with migrating data from memory cells of the memory system that are associated with a first storage density to memory cells of the memory system that are associated with a second storage density.

In some examples, the wear leveling evaluation component 335 may be configured as or otherwise support a means for determining that a lowest quantity of program/erase cycles associated with a plurality of blocks of memory cells of the memory system satisfies a threshold, and determining to perform the first wear leveling operation at a memory system may be based at least in part on determining that the lowest quantity of program/erase cycles satisfies the threshold.

In some examples, to support performing the first wear leveling operation, the wear leveling component 325 may be configured as or otherwise support a means for reading information from a first block of memory cells associated with a lowest quantity of program/erase cycles. In some examples, to support performing the first wear leveling operation, the wear leveling component 325 may be configured as or otherwise support a means for writing the information to a second block of memory cells different than the first block of memory cells.

In some examples, the wear leveling component 325 may be configured as or otherwise support a means for performing the second wear leveling operation at the memory system based at least in part on determining to perform the second wear leveling operation. In some examples, the wear leveling evaluation component 335 may be configured as or otherwise support a means for determining a third quantity of write operations at the memory system, less than the second quantity of write operations, based at least in part on determining to perform the second wear leveling operation. In some examples, the wear leveling evaluation component 335 may be configured as or otherwise support a means for determining whether to perform a third wear leveling operation at the memory system based at least in part on performing the third quantity of write operations at the memory system.

In some examples, the wear leveling component 325 may be configured as or otherwise support a means for refraining from performing the second wear leveling operation at the memory system based at least in part on determining to not perform the second wear leveling operation. In some examples, the wear leveling rate component 330 may be configured as or otherwise support a means for determining a third quantity of write operations at the memory system, greater than the second quantity of write operations, based at least in part on determining to not perform the second wear leveling operation. In some examples, the wear leveling evaluation component 335 may be configured as or otherwise support a means for determining whether to perform the wear leveling operation at the memory system based at least in part on performing the third quantity of write operations at the memory system.

In some examples, the wear leveling component 325 may be configured as or otherwise support a means for performing wear leveling at a memory system in accordance with a first rate of performing wear leveling operations. In some examples, the wear leveling evaluation component 335 may be configured as or otherwise support a means for determining that a wear characteristic of the memory system satisfies a threshold. In some examples, the wear leveling component 325 may be configured as or otherwise support a means for performing the wear leveling at the memory system in accordance with a second rate of performing wear leveling operations based at least in part on determining that the wear characteristic satisfies the threshold.

In some examples, performing the wear leveling at the memory system in accordance with the first rate of performing wear leveling operations includes evaluating, in accordance with the first rate of performing wear leveling operations, whether a lowest quantity of program/erase cycles associated with a plurality of blocks of memory cells of the memory system satisfies a second threshold. In some examples, performing the wear leveling at the memory system in accordance with the second rate of performing wear leveling operations includes evaluating, in accordance with the second rate of performing wear leveling operations, whether the lowest quantity of program/erase cycles associated with a plurality of blocks of memory cells of the memory system satisfies the second threshold.

In some examples, performing the wear leveling at the memory system in accordance with the first rate of performing wear leveling operations includes transferring, at a first rate that is less than or equal to the first rate of wear leveling operations, information from a respective blocks of memory cells associated with a lowest quantity of program/erase cycles to respective second blocks of memory cells. In some examples, performing the wear leveling at the memory system in accordance with the second rate of wear leveling operations includes transferring, at a second rate that is less than or equal to the second rate of wear leveling operations, information from respective first blocks of memory cells associated with a lowest quantity of program/erase cycles to respective second blocks of memory cells.

In some examples, to support determining that the wear characteristic of the memory system satisfies a threshold, the wear leveling evaluation component 335 may be configured as or otherwise support a means for determining to perform a transfer of information from a first block of memory cells associated with a first quantity of program/erase cycles to a second block of memory cells associated with a second quantity of program/erase cycles that is greater than the first quantity.

In some examples, to support determining that the wear characteristic of the memory system satisfies a threshold, the wear leveling evaluation component 335 may be configured as or otherwise support a means for determining that a quantity of access operations between determining to perform a first wear leveling operation and determining to perform a second wear leveling operation satisfies a threshold quantity of access operations.

In some examples, the second rate of wear leveling operations may be greater than the first rate of wear leveling operations.

In some examples, to support determining that the wear characteristic of the memory system satisfies a threshold, the wear leveling evaluation component 335 may be configured as or otherwise support a means for determining to refrain from performing a transfer of information from a block of memory cells associated with a lowest quantity of program/erase cycles of a plurality of blocks of memory cells.

In some examples, to support determining that the wear characteristic of the memory system satisfies a threshold, the wear leveling evaluation component 335 may be configured as or otherwise support a means for determining that a quantity of access operations between determining to refrain from performing a first wear leveling operation and determining to refrain from performing a second wear leveling operation satisfies a threshold quantity of access operations.

In some examples, the second rate of wear leveling operations may be less than the first rate of wear leveling operations.

In some examples, performing the wear leveling at the memory system in accordance with the first rate of wear leveling operations is based at least in part on performing a first quantity of data migrations, between wear leveling operations, from memory cells of the memory system that are associated with a first storage density to memory cells of the memory system that are associated with a second storage density. In some examples, performing the wear leveling at the memory system in accordance with the second rate of wear leveling operations is based at least in part on performing a second quantity of data migrations, between wear leveling operations, from the memory cells of the memory system that are associated with a first storage density to the memory cells of the memory system that are associated with a second storage density.

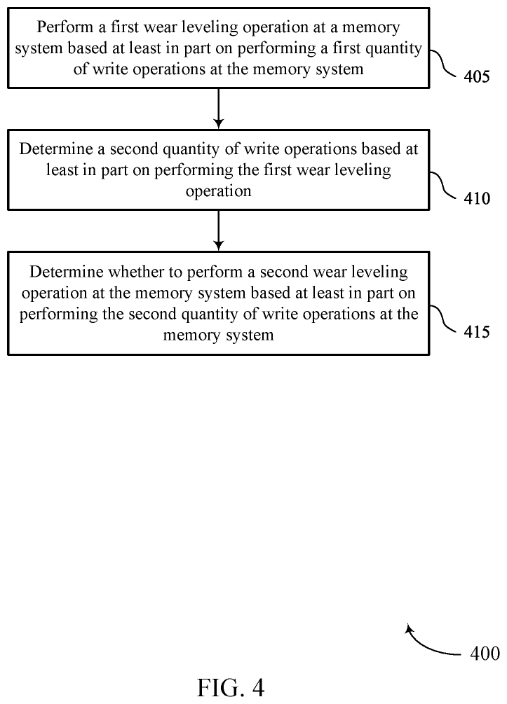

FIG. 4 shows a flowchart illustrating a method 400 that supports adaptive wear leveling for a memory system in accordance with examples as disclosed herein. The operations of method 400 may be implemented by a memory system or its components as described herein. For example, the operations of method 400 may be performed by a memory system as described with reference to FIGS. 1 through 3. In some examples, a memory system may execute a set of instructions to control the functional elements of the device to perform the described functions. Additionally, or alternatively, the memory system may perform aspects of the described functions using special-purpose hardware.

At 405, the method may include performing a first wear leveling operation at a memory system based at least in part on performing a first quantity of write operations at the memory system. The operations of 405 may be performed in accordance with examples as disclosed herein. In some examples, aspects of the operations of 405 may be performed by a wear leveling component 325 as described with reference to FIG. 3.

At 410, the method may include determining a second quantity of write operations based at least in part on performing the first wear leveling operation. The operations of 410 may be performed in accordance with examples as disclosed herein. In some examples, aspects of the operations of 410 may be performed by a wear leveling rate component 330 as described with reference to FIG. 3.

At 415, the method may include determining whether to perform a second wear leveling operation at the memory system based at least in part on performing the second quantity of write operations at the memory system. The operations of 415 may be performed in accordance with examples as disclosed herein. In some examples, aspects of the operations of 415 may be performed by a wear leveling evaluation component 335 as described with reference to FIG. 3.

In some examples, an apparatus as described herein may perform a method or methods, such as the method 400. The apparatus may include features, circuitry, logic, means, or instructions (e.g., a non-transitory computer-readable medium storing instructions executable by a processor), or any combination thereof for performing the following aspects of the present disclosure:
Aspect 1: A method, apparatus, or non-transitory computer-readable medium including operations, features, circuitry, logic, means, or instructions, or any combination thereof for performing a first wear leveling operation at a memory system based at least in part on performing a first quantity of write operations at the memory system; determining a second quantity of write operations based at least in part on performing the first wear leveling operation; and determining whether to perform a second wear leveling operation at the memory system based at least in part on performing the second quantity of write operations at the memory system.
Aspect 2: The method, apparatus, or non-transitory computer-readable medium of aspect 1, where the second quantity of write operations is less than the first quantity of write operations.
Aspect 3: The method, apparatus, or non-transitory computer-readable medium of any of aspects 1 through 2, further including operations, features, circuitry, logic, means, or instructions, or any combination thereof for determining whether to perform the first wear leveling operation in accordance with a first rate of evaluation that is associated with the first quantity of write operations, where performing the first wear leveling operation is based at least on determining to perform the first wear leveling operation; and determining whether to perform the second wear leveling operation in accordance with a second rate of evaluation, greater than the first rate of evaluation, that associated with the second quantity of write operations.
Aspect 4: The method, apparatus, or non-transitory computer-readable medium of any of aspects 1 through 3, further including operations, features, circuitry, logic, means, or instructions, or any combination thereof for receiving a first set of one or more commands from a host system; performing the first quantity of write operations based at least in part on the first set of one or more commands from the host system; receiving a second set of one or more commands from the host system; and performing the second quantity of write operations based at least in part on the second set of one or more commands from the host system.
Aspect 5: The method, apparatus, or non-transitory computer-readable medium of any of aspects 1 through 4, where write operations of the first quantity of write operations and write operations of the second quantity of write operations are associated with migrating data from memory cells of the memory system that are associated with a first storage density to memory cells of the memory system that are associated with a second storage density.
Aspect 6: The method, apparatus, or non-transitory computer-readable medium of any of aspects 1 through 5, further including operations, features, circuitry, logic, means, or instructions, or any combination thereof for determining that a lowest quantity of program/erase cycles associated with a plurality of blocks of memory cells of the memory system satisfies a threshold, where performing the first wear leveling operation at a memory system is based at least in part on determining that the lowest quantity of program/erase cycles satisfies the threshold.
Aspect 7: The method, apparatus, or non-transitory computer-readable medium of any of aspects 1 through 6, where performing the first wear leveling operation includes operations, features, circuitry, logic, means, or instructions, or any combination thereof for reading information from a first block of memory cells associated with a lowest quantity of program/erase cycles and writing the information to a second block of memory cells different than the first block of memory cells.
Aspect 8: The method, apparatus, or non-transitory computer-readable medium of any of aspects 1 through 7, further including operations, features, circuitry, logic, means, or instructions, or any combination thereof for performing the second wear leveling operation at the memory system based at least in part on determining to perform the second wear leveling operation; determining a third quantity of write operations at the memory system, less than the second quantity of write operations, based at least in part on determining to perform the second wear leveling operation; and determining whether to perform a third wear leveling operation at the memory system based at least in part on performing the third quantity of write operations at the memory system.
Aspect 9: The method, apparatus, or non-transitory computer-readable medium of any of aspects 1 through 7, further including operations, features, circuitry, logic, means, or instructions, or any combination thereof for refraining from performing the second wear leveling operation at the memory system based at least in part on determining to not perform the second wear leveling operation; determining a third quantity of write operations at the memory system, greater than the second quantity of write operations, based at least in part on determining to not perform the second wear leveling operation; and determining whether to perform a third wear leveling operation at the memory system based at least in part on performing the third quantity of write operations at the memory system.

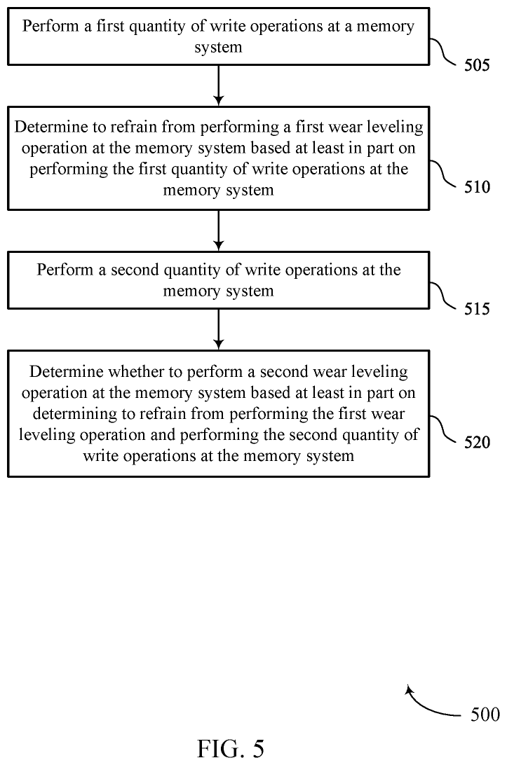

FIG. 5 shows a flowchart illustrating a method 500 that supports adaptive wear leveling for a memory system in accordance with examples as disclosed herein. The operations of method 500 may be implemented by a memory system or its components as described herein. For example, the operations of method 500 may be performed by a memory system as described with reference to FIGS. 1 through 3. In some examples, a memory system may execute a set of instructions to control the functional elements of the device to perform the described functions. Additionally, or alternatively, the memory system may perform aspects of the described functions using special-purpose hardware.

At 505, the method may include performing a first quantity of write operations at a memory system. The operations of 505 may be performed in accordance with examples as disclosed herein. In some examples, aspects of the operations of 505 may be performed by an access component 340 as described with reference to FIG. 3.

At 510, the method may include determining to refrain from performing a first wear leveling operation at the memory system based at least in part on performing the first quantity of write operations at the memory system. The operations of 510 may be performed in accordance with examples as disclosed herein. In some examples, aspects of the operations of 510 may be performed by a wear leveling evaluation component 335 as described with reference to FIG. 3.

At 515, the method may include performing a second quantity of write operations at the memory system. The operations of 515 may be performed in accordance with examples as disclosed herein. In some examples, aspects of the operations of 515 may be performed by an access component 340 as described with reference to FIG. 3.

At 520, the method may include determining whether to perform a second wear leveling operation at the memory system based at least in part on determining to refrain from performing the first wear leveling operation and performing the second quantity of write operations at the memory system. The operations of 520 may be performed in accordance with examples as disclosed herein. In some examples, aspects of the operations of 520 may be performed by a wear leveling evaluation component 335 as described with reference to FIG. 3.

In some examples, an apparatus as described herein may perform a method or methods, such as the method 500. The apparatus may include features, circuitry, logic, means, or instructions (e.g., a non-transitory computer-readable medium storing instructions executable by a processor), or any combination thereof for performing the following aspects of the present disclosure:
Aspect 10: A method, apparatus, or non-transitory computer-readable medium including operations, features, circuitry, logic, means, or instructions, or any combination thereof for performing a first quantity of write operations at a memory system; determining to refrain from performing a first wear leveling operation at the memory system based at least in part on performing the first quantity of write operations at the memory system; performing a second quantity of write operations at the memory system; and determining whether to perform a second wear leveling operation at the memory system based at least in part on determining to refrain from performing the first wear leveling operation and performing the second quantity of write operations at the memory system.
Aspect 11: The method, apparatus, or non-transitory computer-readable medium of aspect 10, where the second quantity of write operations is greater than the first quantity of write operations.
Aspect 12: The method, apparatus, or non-transitory computer-readable medium of any of aspects 10 through 11, further including operations, features, circuitry, logic, means, or instructions, or any combination thereof for determining whether to perform the first wear leveling operation in accordance with a first rate of evaluation that is associated with the first quantity of write operations, where determining to refrain from performing the first wear leveling operation is based at least on the determining whether to perform the first wear leveling operation; and determining whether to perform the second wear leveling operation in accordance with a second rate of evaluation, less than the first rate of evaluation, that is associated with the second quantity of write operations.
Aspect 13: The method, apparatus, or non-transitory computer-readable medium of any of aspects 10 through 12, further including operations, features, circuitry, logic, means, or instructions, or any combination thereof for receiving a first set of one or more commands from a host system, where performing the first quantity of write operations is based at least in part on the first set of one or more commands from the host system; and receiving a second set of one or more commands from the host system, where performing the second quantity of write operations is based at least in part on the second set of one or more commands from the host system.
Aspect 14: The method, apparatus, or non-transitory computer-readable medium of any of aspects 10 through 13, where write operations of the first quantity of write operations and of the second quantity of write operations are associated with migrating data from memory cells of the memory system that are associated with a first storage density to memory cells of the memory system that are associated with a second storage density.
Aspect 15: The method, apparatus, or non-transitory computer-readable medium of any of aspects 10 through 14, further including operations, features, circuitry, logic, means, or instructions, or any combination thereof for determining that a lowest quantity of program/erase cycles associated with a plurality of blocks of memory cells of the memory system satisfies a threshold, where determining to perform the first wear leveling operation at a memory system is based at least in part on determining that the lowest quantity of program/erase cycles satisfies the threshold.
Aspect 16: The method, apparatus, or non-transitory computer-readable medium of any of aspects 10 through 15, where performing the first wear leveling operation includes operations, features, circuitry, logic, means, or instructions, or any combination thereof for reading information from a first block of memory cells associated with a lowest quantity of program/erase cycles and writing the information to a second block of memory cells different than the first block of memory cells.
Aspect 17: The method, apparatus, or non-transitory computer-readable medium of any of aspects 10 through 16, further including operations, features, circuitry, logic, means, or instructions, or any combination thereof for performing the second wear leveling operation at the memory system based at least in part on determining to perform the second wear leveling operation; determining a third quantity of write operations at the memory system, less than the second quantity of write operations, based at least in part on determining to perform the second wear leveling operation; and determining whether to perform a third wear leveling operation at the memory system based at least in part on performing the third quantity of write operations at the memory system.
Aspect 18: The method, apparatus, or non-transitory computer-readable medium of any of aspects 10 through 16, further including operations, features, circuitry, logic, means, or instructions, or any combination thereof for refraining from performing the second wear leveling operation at the memory system based at least in part on determining to not perform the second wear leveling operation; determining a third quantity of write operations at the memory system, greater than the second quantity of write operations, based at least in part on determining to not perform the second wear leveling operation; and determining whether to perform the wear leveling operation at the memory system based at least in part on performing the third quantity of write operations at the memory system.

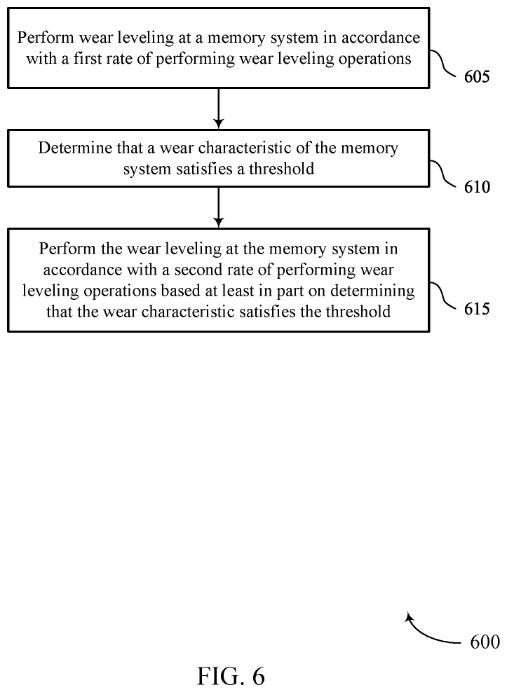

FIG. 6 shows a flowchart illustrating a method 600 that supports adaptive wear leveling for a memory system in accordance with examples as disclosed herein. The operations of method 600 may be implemented by a memory system or its components as described herein. For example, the operations of method 600 may be performed by a memory system as described with reference to FIGS. 1 through 3. In some examples, a memory system may execute a set of instructions to control the functional elements of the device to perform the described functions. Additionally, or alternatively, the memory system may perform aspects of the described functions using special-purpose hardware.

At 605, the method may include performing wear leveling at a memory system in accordance with a first rate of performing wear leveling operations. The operations of 605 may be performed in accordance with examples as disclosed herein. In some examples, aspects of the operations of 605 may be performed by a wear leveling component 325 as described with reference to FIG. 3.

At 610, the method may include determining that a wear characteristic of the memory system satisfies a threshold. The operations of 610 may be performed in accordance with examples as disclosed herein. In some examples, aspects of the operations of 610 may be performed by a wear leveling evaluation component 335 as described with reference to FIG. 3.

At 615, the method may include performing the wear leveling at the memory system in accordance with a second rate of performing wear leveling operations based at least in part on determining that the wear characteristic satisfies the threshold. The operations of 615 may be performed in accordance with examples as disclosed herein. In some examples, aspects of the operations of 615 may be performed by a wear leveling component 325 as described with reference to FIG. 3.

In some examples, an apparatus as described herein may perform a method or methods, such as the method 600. The apparatus may include features, circuitry, logic, means, or instructions (e.g., a non-transitory computer-readable medium storing instructions executable by a processor), or any combination thereof for performing the following aspects of the present disclosure:
Aspect 19: A method, apparatus, or non-transitory computer-readable medium including operations, features, circuitry, logic, means, or instructions, or any combination thereof for performing wear leveling at a memory system in accordance with a first rate of performing wear leveling operations; determining that a wear characteristic of the memory system satisfies a threshold; and performing the wear leveling at the memory system in accordance with a second rate of performing wear leveling operations based at least in part on determining that the wear characteristic satisfies the threshold.
Aspect 20: The method, apparatus, or non-transitory computer-readable medium of aspect 19, where performing the wear leveling at the memory system in accordance with the first rate of performing wear leveling operations includes evaluating, in accordance with the first rate of performing wear leveling operations, whether a lowest quantity of program/erase cycles associated with a plurality of blocks of memory cells of the memory system satisfies a second threshold and performing the wear leveling at the memory system in accordance with the second rate of performing wear leveling operations includes evaluating, in accordance with the second rate of performing wear leveling operations, whether the lowest quantity of program/erase cycles associated with a plurality of blocks of memory cells of the memory system satisfies the second threshold.
Aspect 21: The method, apparatus, or non-transitory computer-readable medium of any of aspects 19 through 20, where performing the wear leveling at the memory system in accordance with the first rate of performing wear leveling operations includes transferring, at a first rate that is less than or equal to the first rate of wear leveling operations, information from a respective blocks of memory cells associated with a lowest quantity of program/erase cycles to respective second blocks of memory cells and performing the wear leveling at the memory system in accordance with the second rate of wear leveling operations includes transferring, at a second rate that is less than or equal to the second rate of wear leveling operations, information from respective first blocks of memory cells associated with a lowest quantity of program/erase cycles to respective second blocks of memory cells.
Aspect 22: The method, apparatus, or non-transitory computer-readable medium of any of aspects 19 through 21, where determining that the wear characteristic of the memory system satisfies a threshold includes operations, features, circuitry, logic, means, or instructions, or any combination thereof for determining to perform a transfer of information from a first block of memory cells associated with a first quantity of program/erase cycles to a second block of memory cells associated with a second quantity of program/erase cycles that is greater than the first quantity.
Aspect 23: The method, apparatus, or non-transitory computer-readable medium of any of aspects 19 through 22, where determining that the wear characteristic of the memory system satisfies a threshold includes operations, features, circuitry, logic, means, or instructions, or any combination thereof for determining that a quantity of access operations between determining to perform a first wear leveling operation and determining to perform a second wear leveling operation satisfies a threshold quantity of access operations.
Aspect 24: The method, apparatus, or non-transitory computer-readable medium of aspect 23, where the second rate of wear leveling operations is greater than the first rate of wear leveling operations.
Aspect 25: The method, apparatus, or non-transitory computer-readable medium of any of aspects 19 through 21, where determining that the wear characteristic of the memory system satisfies a threshold includes operations, features, circuitry, logic, means, or instructions, or any combination thereof for determining to refrain from performing a transfer of information from a block of memory cells associated with a lowest quantity of program/erase cycles of a plurality of blocks of memory cells.
Aspect 26: The method, apparatus, or non-transitory computer-readable medium of any of aspects 19 through 21 or 25, where determining that the wear characteristic of the memory system satisfies a threshold includes operations, features, circuitry, logic, means, or instructions, or any combination thereof for determining that a quantity of access operations between determining to refrain from performing a first wear leveling operation and determining to refrain from performing a second wear leveling operation satisfies a threshold quantity of access operations.
Aspect 27: The method, apparatus, or non-transitory computer-readable medium of aspect 26, where the second rate of wear leveling operations is less than the first rate of wear leveling operations.
Aspect 28: The method, apparatus, or non-transitory computer-readable medium of any of aspects 19 through 27, where performing the wear leveling at the memory system in accordance with the first rate of wear leveling operations is based at least in part on performing a first quantity of data migrations, between wear leveling operations, from memory cells of the memory system that are associated with a first storage density to memory cells of the memory system that are associated with a second storage density and performing the wear leveling at the memory system in accordance with the second rate of wear leveling operations is based at least in part on performing a second quantity of data migrations, between wear leveling operations, from the memory cells of the memory system that are associated with a first storage density to the memory cells of the memory system that are associated with a second storage density.

It should be noted that the described techniques include possible implementations, and that the operations and the steps may be rearranged or otherwise modified and that other implementations are possible. Further, portions from two or more of the methods may be combined.

An apparatus is described. The following provides an overview of aspects of the apparatus as described herein:
Aspect 29: An apparatus, including: a plurality of memory cells; and circuitry configured to cause the apparatus to: perform a first wear leveling operation on a plurality of memory cells based at least in part on performing a first quantity of write operations on the plurality of memory cells; determine a second quantity of write operations based at least in part on performing the first wear leveling operation; and determine whether to perform a second wear leveling operation on the plurality of memory cells based at least in part on performing the second quantity of write operations on the plurality of memory cells.

An apparatus is described. The following provides an overview of aspects of the apparatus as described herein:
Aspect 30: An apparatus, including: a plurality of memory cells; and circuitry configured to cause the apparatus to: perform a first quantity of write operations at a memory system; determine to refrain from performing a first wear leveling operation at the memory system based at least in part on performing the first quantity of write operations at the memory system; perform a second quantity of write operations at the memory system; and determine whether to perform a second wear leveling operation at the memory system based at least in part on determining to refrain from performing the first wear leveling operation and performing the second quantity of write operations at the memory system.

Information and signals described herein may be represented using any of a variety of different technologies and techniques. For example, data, instructions, commands, information, signals, bits, symbols, and chips that may be referenced throughout the description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit based on the operation of the device that includes the connected components. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” refers to a condition of moving from an open-circuit relationship between components in which signals are not presently capable of being communicated between the components over a conductive path to a closed-circuit relationship between components in which signals are capable of being communicated between components over the conductive path. If a component, such as a controller, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other if the switch is open. If a controller isolates two components, the controller affects a change that prevents signals from flowing between the components using a conductive path that previously permitted signals to flow.

The terms “if,” “when,” “based on,” or “based at least in part on” may be used interchangeably. In some examples, if the terms “if,” “when,” “based on,” or “based at least in part on” are used to describe a conditional action, a conditional process, or connection between portions of a process, the terms may be interchangeable.

The term “in response to” may refer to one condition or action occurring at least partially, if not fully, as a result of a previous condition or action. For example, a first condition or action may be performed and second condition or action may at least partially occur as a result of the previous condition or action occurring (whether directly after or after one or more other intermediate conditions or actions occurring after the first condition or action).

Additionally, the terms “directly in response to” or “in direct response to” may refer to one condition or action occurring as a direct result of a previous condition or action. In some examples, a first condition or action may be performed and second condition or action may occur directly as a result of the previous condition or action occurring independent of whether other conditions or actions occur. In some examples, a first condition or action may be performed and second condition or action may occur directly as a result of the previous condition or action occurring, such that no other intermediate conditions or actions occur between the earlier condition or action and the second condition or action or a limited quantity of one or more intermediate steps or actions occur between the earlier condition or action and the second condition or action. Any condition or action described herein as being performed “based on,” “based at least in part on,” or “in response to” some other step, action, event, or condition may additionally or alternatively (e.g., in an alternative example) be performed “in direct response to” or “directly in response to” such other condition or action unless otherwise specified.

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorous, boron, or arsenic. Doping may be performed during the initial formation or growth of the substrate, by ion-implantation, or by any other doping means.

A switching component or a transistor discussed herein may represent a field-effect transistor (FET) and comprise a three terminal device including a source, drain, and gate. The terminals may be connected to other electronic elements through conductive materials, e.g., metals. The source and drain may be conductive and may comprise a heavily-doped, e.g., degenerate, semiconductor region. The source and drain may be separated by a lightly-doped semiconductor region or channel. If the channel is n-type (i.e., majority carriers are electrons), then the FET may be referred to as an n-type FET. If the channel is p-type (i.e., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” if a voltage greater than or equal to the transistor's threshold voltage is applied to the transistor gate. The transistor may be “off” or “deactivated” if a voltage less than the transistor's threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a hyphen and a second label that distinguishes among the similar components. If just the first reference label is used in the specification, the description is applicable to any one of the similar components having the same first reference label irrespective of the second reference label.

The functions described herein may be implemented in hardware, software executed by a processor, firmware, or any combination thereof. If implemented in software executed by a processor, the functions may be stored on or transmitted over, as one or more instructions or code, a computer-readable medium. Other examples and implementations are within the scope of the disclosure and appended claims. For example, due to the nature of software, the described functions can be implemented using software executed by a processor, hardware, firmware, hardwiring, or combinations of any of these. Features implementing functions may also be physically located at various positions, including being distributed such that portions of functions are implemented at different physical locations.

For example, the various illustrative blocks and components described in connection with the disclosure herein may be implemented or performed with a general-purpose processor, a DSP, an ASIC, an FPGA or other programmable logic device, discrete gate or transistor logic, discrete hardware components, or any combination thereof designed to perform the functions described herein. A general-purpose processor may be a microprocessor, but in the alternative, the processor may be any processor, controller, microcontroller, or state machine. A processor may be implemented as a combination of computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

Computer-readable media includes both non-transitory computer storage media and communication media including any medium that facilitates transfer of a computer program from one place to another. A non-transitory storage medium may be any available medium that can be accessed by a general purpose or special purpose computer. By way of example, and not limitation, non-transitory computer-readable media can comprise RAM, ROM, electrically erasable programmable read-only memory (EEPROM), compact disk (CD) ROM or other optical disk storage, magnetic disk storage or other magnetic storage devices, or any other non-transitory medium that can be used to carry or store desired program code means in the form of instructions or data structures and that can be accessed by a general-purpose or special-purpose computer, or a general-purpose or special-purpose processor. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, include CD, laser disc, optical disc, digital versatile disc (DVD), floppy disk, and Blu-ray disc, where disks usually reproduce data magnetically, while discs reproduce data optically with lasers. Combinations of these are also included within the scope of computer-readable media.

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A method, comprising:
performing a first wear leveling operation at a memory system based at least in part on performing a first quantity of write operations at the memory system;
determining a second quantity of write operations based at least in part on performing the first wear leveling operation; and
determining whether to perform a second wear leveling operation at the memory system based at least in part on performing the second quantity of write operations at the memory system.

2. The method of claim 1, wherein the second quantity of write operations is less than the first quantity of write operations.

3. The method of claim 1, further comprising:
determining whether to perform the first wear leveling operation in accordance with a first rate of evaluation that is associated with the first quantity of write operations, wherein performing the first wear leveling operation is based at least in part on determining to perform the first wear leveling operation; and
determining whether to perform the second wear leveling operation in accordance with a second rate of evaluation, greater than the first rate of evaluation, that associated with the second quantity of write operations.

4. The method of claim 1, further comprising:
receiving a first set of one or more commands from a host system;
performing the first quantity of write operations based at least in part on the first set of one or more commands from the host system;
receiving a second set of one or more commands from the host system; and
performing the second quantity of write operations based at least in part on the second set of one or more commands from the host system.

5. The method of claim 1, wherein write operations of the first quantity of write operations and write operations of the second quantity of write operations are associated with migrating data from memory cells of the memory system that are associated with a first storage density to memory cells of the memory system that are associated with a second storage density.

6. The method of claim 1, further comprising:
determining that a lowest quantity of program/erase cycles associated with a plurality of blocks of memory cells of the memory system satisfies a threshold, wherein performing the first wear leveling operation at a memory system is based at least in part on determining that the lowest quantity of program/erase cycles satisfies the threshold.

7. The method of claim 1, wherein performing the first wear leveling operation comprises:
reading information from a first block of memory cells associated with a lowest quantity of program/erase cycles; and
writing the information to a second block of memory cells different than the first block of memory cells.

8. The method of claim 1, further comprising:
performing the second wear leveling operation at the memory system based at least in part on determining to perform the second wear leveling operation;
determining a third quantity of write operations at the memory system, less than the second quantity of write operations, based at least in part on determining to perform the second wear leveling operation; and
determining whether to perform a third wear leveling operation at the memory system based at least in part on performing the third quantity of write operations at the memory system.

9. The method of claim 1, further comprising:
refraining from performing the second wear leveling operation at the memory system based at least in part on determining to not perform the second wear leveling operation;
determining a third quantity of write operations at the memory system, greater than the second quantity of write operations, based at least in part on determining to not perform the second wear leveling operation; and
determining whether to perform a third wear leveling operation at the memory system based at least in part on performing the third quantity of write operations at the memory system.

10. An apparatus, comprising:
a plurality of memory cells; and
circuitry configured to cause the apparatus to:
perform a first wear leveling operation on a plurality of memory cells based at least in part on performing a first quantity of write operations on the plurality of memory cells;
determine a second quantity of write operations based at least in part on performing the first wear leveling operation; and
determine whether to perform a second wear leveling operation on the plurality of memory cells based at least in part on performing the second quantity of write operations on the plurality of memory cells.

11. A method, comprising:
performing a first quantity of write operations at a memory system;
determining to refrain from performing a first wear leveling operation at the memory system based at least in part on performing the first quantity of write operations at the memory system;
performing a second quantity of write operations at the memory system; and
determining whether to perform a second wear leveling operation at the memory system based at least in part on determining to refrain from performing the first wear leveling operation and performing the second quantity of write operations at the memory system.

12. The method of claim 11, wherein the second quantity of write operations is greater than the first quantity of write operations.

13. The method of claim 11, further comprising:
determining whether to perform the first wear leveling operation in accordance with a first rate of evaluation that is associated with the first quantity of write operations, wherein determining to refrain from performing the first wear leveling operation is based at least in part on the determining whether to perform the first wear leveling operation; and
determining whether to perform the second wear leveling operation in accordance with a second rate of evaluation, less than the first rate of evaluation, that is associated with the second quantity of write operations.

14. The method of claim 11, further comprising:
receiving a first set of one or more commands from a host system, wherein performing the first quantity of write operations is based at least in part on the first set of one or more commands from the host system; and
receiving a second set of one or more commands from the host system, wherein performing the second quantity of write operations is based at least in part on the second set of one or more commands from the host system.

15. The method of claim 11, wherein write operations of the first quantity of write operations and of the second quantity of write operations are associated with migrating data from memory cells of the memory system that are associated with a first storage density to memory cells of the memory system that are associated with a second storage density.

16. The method of claim 11, further comprising:
determining that a lowest quantity of program/erase cycles associated with a plurality of blocks of memory cells of the memory system satisfies a threshold, wherein determining to perform the first wear leveling operation at a memory system is based at least in part on determining that the lowest quantity of program/erase cycles satisfies the threshold.

17. The method of claim 11, wherein performing the first wear leveling operation comprises:
reading information from a first block of memory cells associated with a lowest quantity of program/erase cycles; and
writing the information to a second block of memory cells different than the first block of memory cells.

18. The method of claim 11, further comprising:
performing the second wear leveling operation at the memory system based at least in part on determining to perform the second wear leveling operation;
determining a third quantity of write operations at the memory system, less than the second quantity of write operations, based at least in part on determining to perform the second wear leveling operation; and
determining whether to perform a third wear leveling operation at the memory system based at least in part on performing the third quantity of write operations at the memory system.

19. The method of claim 11, further comprising:
refraining from performing the second wear leveling operation at the memory system based at least in part on determining to not perform the second wear leveling operation;
determining a third quantity of write operations at the memory system, greater than the second quantity of write operations, based at least in part on determining to not perform the second wear leveling operation; and
determining whether to perform the wear leveling operation at the memory system based at least in part on performing the third quantity of write operations at the memory system.

20. An apparatus, comprising:
a plurality of memory cells; and
circuitry configured to cause the apparatus to:
perform a first quantity of write operations at a memory system;
determine to refrain from performing a first wear leveling operation at the memory system based at least in part on performing the first quantity of write operations at the memory system;
perform a second quantity of write operations at the memory system; and
determine whether to perform a second wear leveling operation at the memory system based at least in part on determining to refrain from performing the first wear leveling operation and performing the second quantity of write operations at the memory system.

21. A method, comprising:
performing wear leveling at a memory system in accordance with a first rate of performing wear leveling operations;
determining that a wear characteristic of the memory system satisfies a threshold; and
performing the wear leveling at the memory system in accordance with a second rate of performing wear leveling operations based at least in part on determining that the wear characteristic satisfies the threshold.

22. The method of claim 21, wherein:
performing the wear leveling at the memory system in accordance with the first rate of performing wear leveling operations comprises evaluating, in accordance with the first rate of performing wear leveling operations, whether a lowest quantity of program/erase cycles associated with a plurality of blocks of memory cells of the memory system satisfies a second threshold; and
performing the wear leveling at the memory system in accordance with the second rate of performing wear leveling operations comprises evaluating, in accordance with the second rate of performing wear leveling operations, whether the lowest quantity of program/erase cycles associated with a plurality of blocks of memory cells of the memory system satisfies the second threshold.

23. The method of claim 21, wherein:
performing the wear leveling at the memory system in accordance with the first rate of performing wear leveling operations comprises transferring, at a first rate that is less than or equal to the first rate of wear leveling operations, information from a respective blocks of memory cells associated with a lowest quantity of program/erase cycles to respective second blocks of memory cells; and
performing the wear leveling at the memory system in accordance with the second rate of wear leveling operations comprises transferring, at a second rate that is less than or equal to the second rate of wear leveling operations, information from respective first blocks of memory cells associated with a lowest quantity of program/erase cycles to respective second blocks of memory cells.

24. The method of claim 21, wherein determining that the wear characteristic of the memory system satisfies a threshold comprises:
determining to perform a transfer of information from a first block of memory cells associated with a first quantity of program/erase cycles to a second block of memory cells associated with a second quantity of program/erase cycles that is greater than the first quantity.

25. The method of claim 21, wherein determining that the wear characteristic of the memory system satisfies a threshold comprises:
determining that a quantity of access operations between determining to perform a first wear leveling operation and determining to perform a second wear leveling operation satisfies a threshold quantity of access operations.

26. The method of claim 25, wherein the second rate of wear leveling operations is greater than the first rate of wear leveling operations.

27. The method of claim 21, wherein determining that the wear characteristic of the memory system satisfies a threshold comprises:
determining to refrain from performing a transfer of information from a block of memory cells associated with a lowest quantity of program/erase cycles of a plurality of blocks of memory cells.

28. The method of claim 21, wherein determining that the wear characteristic of the memory system satisfies a threshold comprises:
determining that a quantity of access operations between determining to refrain from performing a first wear leveling operation and determining to refrain from performing a second wear leveling operation satisfies a threshold quantity of access operations.

29. The method of claim 28, wherein the second rate of wear leveling operations is less than the first rate of wear leveling operations.

30. The method of claim 21, wherein:
performing the wear leveling at the memory system in accordance with the first rate of wear leveling operations is based at least in part on performing a first quantity of data migrations, between wear leveling operations, from memory cells of the memory system that are associated with a first storage density to memory cells of the memory system that are associated with a second storage density; and
performing the wear leveling at the memory system in accordance with the second rate of wear leveling operations is based at least in part on performing a second quantity of data migrations, between wear leveling operations, from the memory cells of the memory system that are associated with a first storage density to the memory cells of the memory system that are associated with a second storage density.
